(19) United States
(12) Patent Application Publication
(10) Pub. No.: US 2024/0171141 A1
(43) Pub. Date: May 23, 2024

(54) CIRCUIT FOR DETECTING CAPACITANCE WITH DYNAMIC CURRENT MIRROR

(71) Applicant: UIF (University Industry Foundation), Yonsei University, Seoul (KR)

(72) Inventors: Young Cheol Chae, Seoul (KR); Hye Yeon Lee, Seoul (KR)

(73) Assignee: UIF (University Industry Foundation), Yonsei University, Seoul (KR)

(21) Appl. No.: 18/515,271

(22) Filed: Nov. 21, 2023

(30) Foreign Application Priority Data
Nov. 21, 2022 (KR) 10-2022-0155972

(51) Int. Cl. H03F 3/45; H03F 1/34

(52) U.S. Cl. CPC H03F 3/45273; H03F 1/34; H03F 2200/261

(57) ABSTRACT

A capacitance detection circuit using a dynamic current mirror includes a first dynamic current mirror circuit including a reference capacitor connected in series with a first transistor and an input capacitor connected in series with a second transistor, and an oscillator circuit connected to an output node of the first dynamic current mirror circuit and configured to charge an integration capacitance using current output from the first dynamic current mirror circuit. The amount of change in voltage at a first node positioned between a source of the first transistor and the reference capacitor may be identical to the amount of change in voltage at a second node positioned between a source of the second transistor and the input capacitor.

### CROSS-REFERENCE TO RELATED APPLICATIONS

This application claims priority under 35 U.S.C. § 119 to Korean Patent Application No. 10-2022-0155972 filed on Nov. 21, 2022, in the Korean Intellectual Property Office, the disclosures of which are incorporated by reference herein in their entireties.

### BACKGROUND

Embodiments of the present disclosure described herein relate to a capacitance detection circuit.

Capacitance sensors have benefits such as low production cost, stability, and low-power operation compared to other resistors, or optical and inductive sensors, and are used in various ways in real life along with pressure sensors and touch screen sensors. However, there is a problem that power consumed by a circuit including an operational transconductance amplifier increases as an input capacitance value increases in the case of reading capacitance using an OTA-based circuit. Therefore, an OTA-FREE structure is required to design a low-power capacitance detection circuit with a wide dynamic range.

### SUMMARY

Embodiments of the present disclosure provide a capacitance detection circuit with an OTA-FREE structure using a dynamic current mirror.

According to an embodiment, a capacitance detection circuit using a dynamic current mirror includes a first dynamic current mirror circuit including a reference capacitor connected in series with a first transistor and an input capacitor connected in series with a second transistor, and an oscillator circuit connected to an output node of the first dynamic current mirror circuit and configured to charge an integration capacitance using current output from the first dynamic current mirror circuit, wherein an amount of change in voltage at a first node positioned between a source of the first transistor and the reference capacitor may be identical to an amount of change in voltage at a second node positioned between a source of the second transistor and the input capacitor.

According to an embodiment, the first dynamic current mirror circuit may further include a first switch connected in parallel with the reference capacitor and a second switch connected in parallel with the input capacitor.

According to an embodiment, the first switch and the second switch may be closed for a predetermined period of time to discharge the reference capacitor and the input capacitor, respectively.

According to an embodiment, the first dynamic current mirror circuit may further include a first amplifier, and an inverting input terminal of the first amplifier is connected to a drain of the second transistor, and a non-inverting input terminal of the first amplifier may be connected to a third node positioned between a gate of the first transistor and a gate of the second transistor.

According to an embodiment, an output terminal of the amplifier may be connected to a gate of the third transistor, and a source of the third transistor is connected to the drain of the second transistor.

According to an embodiment, an intensity of current input to the oscillator circuit by the first dynamic current mirror circuit may be determined based on a capacitance of the input capacitor with respect to a capacitance of the reference capacitor.

According to an embodiment, the capacitance detection circuit may further include a power circuit connected to an input node of the first dynamic current mirror circuit to supply power to the first dynamic current mirror circuit.

According to an embodiment, the power circuit may include a current source independent of supply voltage of the capacitance detection circuit, and a second current mirror circuit, and an intensity of current output from the second current mirror circuit may be identical to an intensity of current supplied by the current source and be independently of the supply voltage.

According to some embodiments of the present disclosure, it is possible to implement a capacitance detection circuit capable of detecting capacitance over a wide dynamic range by designing an OTA-FREE capacitance detection circuit.

According to some embodiments of the present disclosure, it is possible to improve the area efficiency of circuits by designing an OTA-FREE capacitance detection circuit.

According to some embodiments of the present disclosure, it is possible to generate a reference current that is independent of the supply voltage of a capacitance detection circuit using a dynamic current mirror.

### BRIEF DESCRIPTION OF THE FIGURES

FIG. 1 is a block diagram showing a capacitance detection circuit using a dynamic current mirror according to an embodiment of the present disclosure.

FIG. 2 is a circuit diagram of a capacitance detection circuit using a dynamic current mirror according to an embodiment of the present disclosure.

FIG. 3 is a circuit diagram illustrating another example of a capacitance detection circuit using a dynamic current mirror according to an embodiment of the present disclosure.

FIG. 4 shows an example of a control signal and an output signal of a capacitance detection circuit according to an embodiment of the present disclosure.

### DETAILED DESCRIPTION

Hereinafter, specific details for implementing the present disclosure will be described in detail with reference to the accompanying drawings. However, in the following description, detailed descriptions of well-known functions or configurations will be omitted if there is a risk of unnecessarily obscuring the gist of the present disclosure.

In the accompanying drawings, identical or corresponding components are given the same reference numerals. Additionally, in the description of embodiments, overlapping descriptions of identical or corresponding components may be omitted. However, even if descriptions of components are omitted, it is not intended that such components are not included in any embodiment.

Benefits and features of embodiments and methods for achieving them will be apparent with reference to embodiments described below in detail in conjunction with the accompanying drawings. However, the present disclosure is not limited to the embodiments disclosed below, but may be implemented in various forms, and these embodiments are to make the disclosure of the present disclosure complete, and are provided such that this will be thorough and complete and will fully convey the scope of the present disclosure to those of ordinary skill in the art, which is to be defined only by the scope of the claims.

Terms used in the present specification will be briefly described, and the disclosed embodiments will be described in detail. The terms used herein are general terms that are currently widely used as much as possible in consideration of their function in the present disclosure, but may vary depending on the intention of a person skilled in the art in the technical field to which the present disclosure pertains, precedents, or the emergence of new technology. In addition, in certain cases, there are terms arbitrarily selected by the applicant, and in this case, the meaning thereof will be described in detail in the relevant description of the present disclosure. Therefore, the terms used herein should be defined based on the meaning of the terms and the overall content of the present disclosure, rather than simply the names of the terms.

As used herein, singular forms may include plural forms as well unless the context clearly indicates otherwise. Additionally, plural forms include singular forms, unless the context clearly indicates otherwise. In addition, throughout the specification, unless explicitly described to the contrary, the word “comprise” and variations such as “comprises” or “comprising” will be understood to imply the inclusion of stated elements but not the exclusion of any other elements.

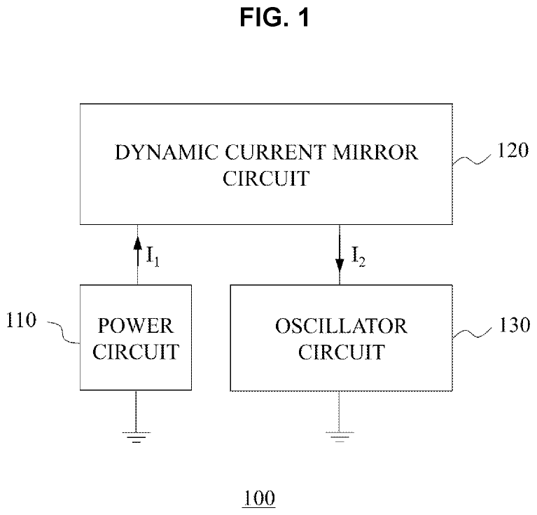

FIG. 1 is a block diagram showing a capacitance detection circuit 100 using a dynamic current mirror according to an embodiment of the present disclosure. As shown, the capacitance detection circuit 100 may include at least one of a power circuit 110, a dynamic current mirror circuit 120, and an oscillator circuit 130.

The power circuit 110 may supply a current I₁ used in the capacitance detection circuit 100. Specifically, the power circuit 110 may be connected to the input node of the dynamic current mirror circuit 120 to supply the current I₁ to the dynamic current mirror circuit 120. Here, the dynamic current mirror circuit 120 may refer to a circuit including an input capacitor (not shown) of which capacitance is to be detected. Meanwhile, the power circuit 110 may exist in a grounded state.

The dynamic current mirror circuit 120 may include a reference capacitor (not shown) and an input capacitor (not shown) of which capacitance is to be detected. Accordingly, the dynamic current mirror circuit 120 may output a current I₂ associated with a reference capacitor and/or an input capacitor using the input current I₁. For example, the dynamic current mirror circuit 120 may be determined based on the capacitance of an input capacitor (hereinafter referred to as “input capacitance”) with respect to the capacitance of the reference capacitor (hereinafter referred to as “reference capacitance”). Meanwhile, the dynamic current mirror circuit 120 may copy current and/or voltage. For example, the dynamic current mirror circuit 120, may be configured such that the voltage of the first node and the voltage of the second node are the same. With the above-described configuration, the current I₂ output from the dynamic current mirror circuit 120 may be calculated based on the relationship between the voltage of the first node and the voltage of the second node. In this case, the current I₂ may be expressed in an equation related to the input current I₁, the input capacitance, and the output capacitance.

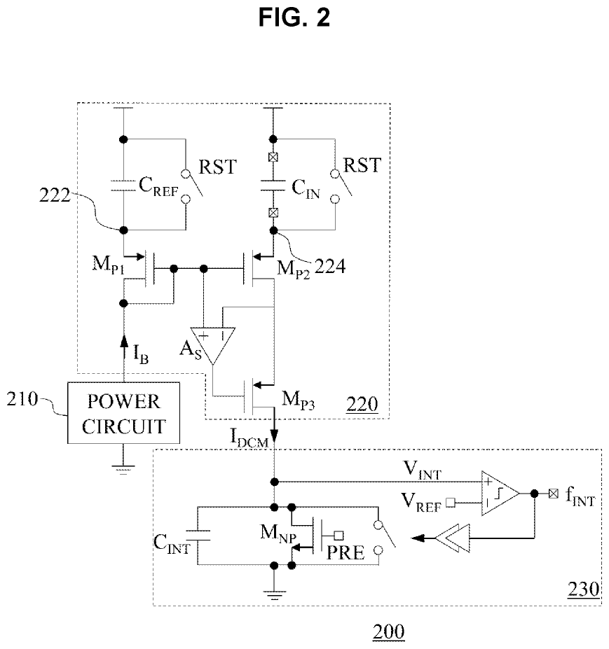

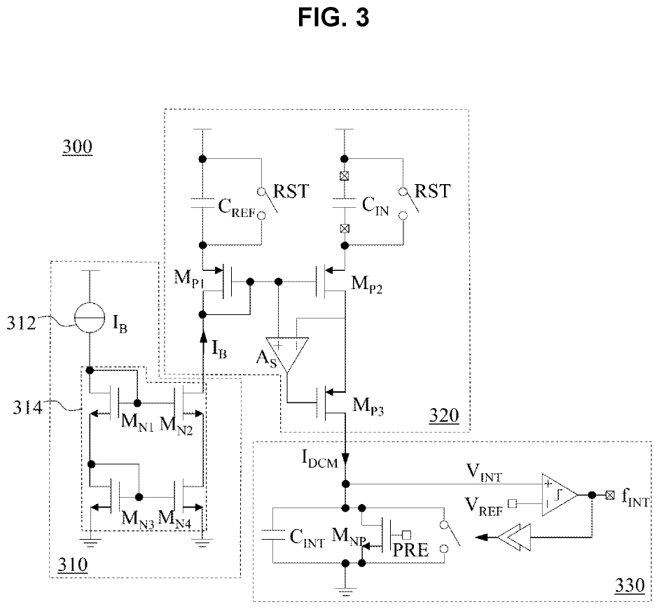

The oscillator circuit 130 connected to the output node of the dynamic current mirror circuit 120 may charge an integration capacitor (not shown) using the current I₂ output from the dynamic current mirror circuit 120. Here, the oscillator circuit 130 may refer to a circuit including a relaxation oscillator. Accordingly, the output current I₂ may be calculated by measuring the output frequency of the oscillator circuit 130, because the output frequency of the oscillator circuit 130 is determined by the output current I₂ and the capacitance of the integration capacitor (hereinafter referred to as “integration capacitance”). In this case, the current I₂ may be expressed in an equation related to the output frequency and the integration capacitance. In conclusion, the input capacitance of the dynamic current mirror circuit 120 may be measured based on the equation(s) calculated according to the operation of each of the components 110 to 130. Detailed description and specific equation(s) related thereto are described in detail later in FIGS. 2 and 3.

FIG. 2 is a circuit diagram of a capacitance detection circuit 200 using a dynamic current mirror according to an embodiment of the present disclosure. As shown, the capacitance detection circuit 200 may include at least one of a power circuit 210, a dynamic current mirror circuit 220, and an oscillator circuit 230. Meanwhile, the capacitance detection circuit 200 of FIG. 2 may correspond to the capacitance detection circuit 100 of FIG. 1. That is, the power circuit 210, the dynamic current mirror circuit 220, and the oscillator circuit 230 may be replaced with the power circuit 110, the dynamic current mirror circuit 120, and the oscillator circuit 130 of FIG. 1, respectively.

The dynamic current mirror circuit 220 may include a reference capacitor CREF connected in series with a first transistor M_{P1}. Additionally, the dynamic current mirror circuit 220 may include an input capacitor C_{IN} connected in series with a second transistor M_{P2}. In this case, the reference capacitor C_{REF} and the first transistor M_{P1} may be symmetrically disposed with the input capacitor C_{IN} and the second transistor M_{P2}, respectively, to form a dynamic current mirror. Accordingly, the relationship between the current I_{B} input to the first transistor M_{P1} and the amount of change in voltage (ΔV_{REF,KNOB}) of the first node 222 may be expressed by Equation 1 below. Additionally, the relationship between the current I_{DCM} output from the second transistor M_{P2} and the amount of change in voltage (ΔV_{KNOB}) of the second node 224 may be expressed by Equation 2 below.

ΔV_{REF,KNOB}/Δt=I_{B}/C_{REF} [Equation 1]

ΔV_{KNOB}/Δt=I_{DCM}/C_{IN} [Equation 2]

Meanwhile, as the dynamic current mirror is formed as described above, the amount of change in voltage at the first node 222 located between the source of the first transistor M_{P1} and the reference capacitor C_{REF} may be identical to the amount of change in voltage at the second node 224 located between the source of the second transistor M_{P2} and the input capacitor C_{IN}. For example, when the amount of change in voltage at the first node 222 is ΔV_{REF,KNOB} and the amount of change in voltage at the second node 224 is ΔV_{KNOB}, the relationship between the amount of change in voltage at the first node 222 and the amount of change in voltage at the second node 224 may be expressed in Equation 3 below. As a result, the current I_{DCM} output from the dynamic current mirror circuit 220 according to Equations 1 to 3 may be defined as Equation 4. That is, the current I_{DCM} output from the dynamic current mirror circuit 220 may be determined based on the value of the input capacitance with respect to the reference capacitance (i.e., the ratio of the reference capacitance and the input capacitance). Therefore, when the reference current I_{B} input to the dynamic current mirror circuit 220 is not sensitive to the supply voltage, the current I_{DCM} output from the dynamic current mirror circuit 220 may also have the same characteristics. To this end, the power circuit 210 that supplies the reference current I_{B} may include a current mirror (not shown) that outputs a constant reference current I_{B} even when the supply voltage changes, of which a detailed description will be provided later in FIG. 3.

ΔV_{REF,KNOB}=ΔV_{KNOB} [Equation 3]

I_{DCM}=I_{B}×C_{IN}/C_{REF} [Equation 4]

Meanwhile, the amount of change in voltage ΔV_{KNOB} at the second node 224 may be expressed as a ramp waveform signal over time t. Accordingly, the current I_{DCM} output from the dynamic current mirror circuit 220 may be defined as Equation 5 as a transient signal.

$${I}_{D C M} ( t ) = {I}_{B} + {I}_{B} \cdot \frac{( {C}_{IN} - {C}_{R E F} )}{{C}_{R E F}} ( 1 - {e}^{- \frac{t}{τ}} ) , \qquad [ Equation 5 ]$$

$$( where τ = {C}_{IN} / {g}_{m p 2} )$$

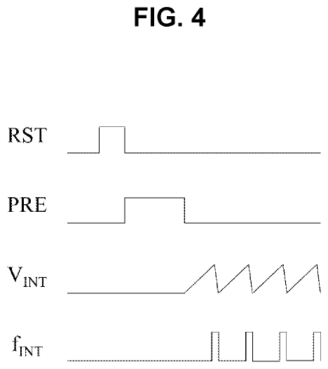

Then, the current I_{DCM} output from the dynamic current mirror circuit 220 may be input to the oscillator circuit 230. Referring to FIG. 4, the output frequency f_{INT} of the oscillator circuit 230 to which the current I_{DCM} is input may be expressed as Equation 6. Referring to Equations 1 to 6 above, the input capacitance C_{IN} of the dynamic current mirror circuit 220 may be detected. For reference, g_{mP2} is transconductance of M_{P2}.

f_{INT}=I_{DCM}/(C_{INT}×V_{REF}) [Equation 6]

FIG. 3 is a circuit diagram illustrating another example of a capacitance detection circuit 300 using a dynamic current mirror according to an embodiment of the present disclosure. As shown, the capacitance detection circuit 300 may include a power circuit 310, a dynamic current mirror circuit 320, and an oscillator circuit 330. Meanwhile, as described above with reference to FIG. 2, when a reference current I_{B} supplied from the power circuit 310 is unrelated to the supply voltage, the current I_{DCM} output from the dynamic current mirror circuit 320 may also have unrelated properties. To this end, the power circuit 310 may include a current source 312 and a current mirror circuit 314.

Referring to FIG. 3, the reference current I_{B} input to the second current mirror circuit 314 by the current source 312 may be copied to the output node of the second current mirror circuit 314 regardless of the change in supply voltage. That is, the second current mirror circuit 314 may output the reference current I_{B} supplied by the current source 312 as it is and provide the reference current I_{B} to the first dynamic current mirror circuit 320.

FIG. 4 shows an example of a control signal and an output signal of a capacitance detection circuit according to an embodiment of the present disclosure. Here, RST is a signal for controlling the switch(s) of the reference capacitor and/or the input capacitor in the dynamic current mirror circuit shown in FIGS. 2 and 3, and PRE is a signal for controlling the switch of the integration capacitor in the oscillator circuit. As shown, the switch(s) of the dynamic current mirror circuit may be first closed to initialize the reference capacitor and input capacitor. Then, when the switch(s) of the dynamic current mirror circuit are opened, the switch connected in parallel with the integration capacitor may be closed. Accordingly, the integration capacitor may be charged to form the input voltage V_{INT} of an amplifier when the switch for the integration capacitor is opened again after predetermined time, and the output voltage frequency f_{INT} of the amplifier in the oscillator circuit.

The above description of the present disclosure is provided to enable those skilled in the art to make or use the present disclosure. Various modifications of the present disclosure will be readily apparent to those skilled in the art, and the generic principles defined herein may be applied to various modifications without departing from the spirit or scope of the present disclosure. Thus, the present disclosure is not intended to be limited to the examples described herein but is intended to be accorded the broadest scope consistent with the principles and novel features disclosed herein.

Although the present disclosure has been described in connection with some embodiments herein, it should be understood that various modifications and changes can be made without departing from the scope of the present disclosure, which can be understood by those skilled in the art to which the present disclosure pertains. In addition, such modifications and changes should be considered within the scope of the claims appended herein.

What is claimed is:

1. A capacitance detection circuit using a dynamic current mirror, comprising:
a first dynamic current mirror circuit including a reference capacitor connected in series with a first transistor and an input capacitor connected in series with a second transistor; and
an oscillator circuit connected to an output node of the first dynamic current mirror circuit and configured to charge an integration capacitance using current output from the first dynamic current mirror circuit,
wherein an amount of change in voltage at a first node positioned between a source of the first transistor and the reference capacitor is configured to be identical to an amount of change in voltage at a second node positioned between a source of the second transistor and the input capacitor.

2. The capacitance detection circuit of claim 1, wherein the first dynamic current mirror circuit further includes a first switch connected in parallel with the reference capacitor and a second switch connected in parallel with the input capacitor.

3. The capacitance detection circuit of claim 2, wherein the first switch and the second switch are configured to be closed for a predetermined period of time to discharge the reference capacitor and the input capacitor, respectively.

4. The capacitance detection circuit of claim 1, wherein the first dynamic current mirror circuit further includes a first amplifier, and
wherein an inverting input terminal of the first amplifier is connected to a drain of the second transistor, and a non-inverting input terminal of the first amplifier is connected to a third node positioned between a gate of the first transistor and a gate of the second transistor.

5. The capacitance detection circuit of claim 4, wherein an output terminal of the amplifier is connected to a gate of the third transistor, and a source of the third transistor is connected to the drain of the second transistor.

6. The capacitance detection circuit of claim 1, wherein an intensity of current input to the oscillator circuit by the first dynamic current mirror circuit is determined based on a capacitance of the input capacitor with respect to a capacitance of the reference capacitor.

7. The capacitance detection circuit of claim 1, further comprising:
a power circuit connected to an input node of the first dynamic current mirror circuit to supply power to the first dynamic current mirror circuit.

8. The capacitance detection circuit of claim 7, wherein the power circuit includes a current source independent of supply voltage of the capacitance detection circuit, and a second current mirror circuit, and
wherein an intensity of current output from the second current mirror circuit is identical to an intensity of current supplied by the current source and is configured independently of the supply voltage.
